(19) United States
(12) Patent Application Publication
(10) Pub. No.: US 2006/0113642 A1
(43) Pub. Date: Jun. 1, 2006

(54) Semiconductor device

(76) Inventors: Atsunori Kajiki, Nagano-shi (JP); Hiroyuki Takatsu, Nagano-shi (JP); Takashi Tsubota, Nagano-shi (JP); Norio Yamanishi, Nagano-shi (JP); Sadakazu Akaike, Nagano-shi (JP); Akinobu Inoue, Nagano-shi (JP)

Correspondence Address: LADAS & PARRY LLP, 224 SOUTH MICHIGAN AVENUE, SUITE 1600, CHICAGO, IL, 60604, US

(21) Appl. No.: 11/251,347

(22) Filed: Oct. 13, 2005

(30) Foreign Application Priority Data
Nov. 30, 2004 (JP) 2004-346848

(51) Int. Cl. H01L 23/552

(52) U.S. Cl. 257/659; 257/660

(57) ABSTRACT

A semiconductor device is disclosed that includes a substrate, electronic components that are arranged at an electronic components mounting area of the substrate, a ground terminal that is arranged within the electronic components mounting area, transfer molded resin that covers the electronic components while exposing the ground terminal, a shield member that covers the electronic components and is connected to the ground terminal, and conductive adhesive that realizes electrical connection between the ground terminal and the shield member.

### BACKGROUND OF THE INVENTION

1. Field of the Invention

The present invention relates to a semiconductor device that includes a shield member for protecting electronic components from electromagnetic waves.

2. Description of the Related Art

A semiconductor device may have a shield case for protecting electronic components that are mounted on its substrate. FIGS. 1 and 2 are cross-sectional views of exemplary semiconductor devices having such a shield case. It is noted that in FIGS. 1 and 2, components that are identical are given the same numerical references. In FIGS. 1 and 2, H1 denotes the height of potting resin 35 (simply referred to as height H1 hereinafter), H2 denotes the height of the semiconductor device 10 shown in FIG. 1 (simply referred to as height H2), H3 denotes the height of the semiconductor device 40 shown in FIG. 2 (simply referred to as height H3 hereinafter) , and C denotes the space between potting resin 35 and a shield case 36 (simply referred to as space C hereinafter).

Referring to FIG. 1, the semiconductor 10 includes a substrate 11, individual components 26 and a semiconductor chip 31 as electronic components, and the shield case 36. The substrate 11 includes a base material 12, vias 13, connectors 14 and 15, a ground terminal 16, an insulating layer 17, wiring 21, a solder resist 23, and solder balls 25. The vias 13 penetrate through the substrate 12 and are configured to realize electrical connection between the connectors 14, 15 and the wiring 21.

The connectors 14 and 15 are arranged on the upper surface of the substrate 12, and are electrically connected to the vias 13. The connectors 14 are electrically connected to the semiconductor chip 31 via gold wires 34. The connectors 15 are electrically connected to the individual components 26. The ground terminal 16 is arranged on the base material 12 at the outer side of the area in which the individual components 26 and the semiconductor chip 31 are mounted. The ground terminal 16 corresponds to a conductor with ground potential. The insulating layer 17 is arranged on the base material 12 to isolate the connectors 14 and 15 from each other.

The wiring 21 includes connection pads 22 to which the solder balls 25 are connected. The wiring 21 is arranged on the bottom surface of the base material 12 and is connected to the vias 13. The solder resist 23 is arranged on the bottom surface side of the base material 12 to expose the connection pads 22 and cover portions of the wiring 21 other than the connection pads 22. The solder balls 25 are connected to the connection pads 22. The solder balls 25 correspond to external connection terminals for connecting the semiconductor device 10 with another substrate such as a motherboard.

The individual components 26 correspond to basic electric components such as a transistor, a diode, a resistor, and a capacitor, and each of the individual components 26 is configured to realize one function. The individual components 26 are electrically connected to the connectors 15 by solder paste 27.

The semiconductor chip 31 includes a semiconductor chip main part 32 and electrode pads 33. The semiconductor chip main part 32 is adhered to the base material 12 by adhesive 24. The semiconductor chip 31 is electrically connected to the substrate 11 via the gold wires 34, which realize connection between the electrode pads 33 and the connectors 14. In other words, the semiconductor chip 31 is bear-chip mounted onto the substrate 11. At the bear-chip mounted area of the substrate 11, the potting resin 35 (resin formed through potting) is arranged to cover the semiconductor chip 31 to protect the gold wires 34 (e.g., see Japanese Laid-Open Patent Publication No. 2001-267628).

It is noted that since the potting resin 35 is formed through potting, it is rather difficult to control the height H1 of the potting resin 35, and the productivity of the semiconductor devices 10 and 40 may decrease as a result. Also, space C has to be provided between the potting resin 35 and the shield case 36/44 of the semiconductor device 10/40 in order to prevent the convex shape of the potting resin 35 from being transferred to the shield case 36/44. As a result, the heights H2 and H3 of the semiconductor devices 10 and 40 may be increased.

Further, in the semiconductor device 10, the ground terminal 16 is arranged at the outer side of the area of the base material 12 in which the individual components 26 and the semiconductor chip 31 are mounted. As a result, the area of the substrate 11 is enlarged to thereby hinder miniaturization of the semiconductor device 10. In the semiconductor device 40, a ground terminal 42 is arranged at the side surface of a base material 41, and the shield case 44 is connected to this ground terminal 42. Consequently, the size of the semiconductor device 40 (i.e., the size of the base material 41 in planar directions) becomes larger than that of the base material 41. Also, the ground terminal 42 and the shield case 44 have to be manually connected to each other using solder so that productivity of the semiconductor device 40 may decrease.

### SUMMARY OF THE INVENTION

The present invention has been conceived in response to one or more of the above problems, and it provides a miniaturized semiconductor device with increased productivity.

According to an aspect of the present invention, a semiconductor device is provided that includes:

a substrate;

a plurality of electronic components that are arranged at an electronic components mounting area of the substrate;

a ground terminal that is arranged within the electronic components mounting area;

a transfer molded resin that covers the electronic components while exposing the ground terminal;

a shield member that covers the electronic components and is connected to the ground terminal; and

a conductive adhesive that realizes electrical connection between the ground terminal and the shield member.

In a preferred embodiment of the present invention, an upper surface of the transfer molded resin is arranged into a smooth plane.

In another preferred embodiment of the present invention, the shield member is arranged into a sheet structure.

### BRIEF DESCRIPTION OF THE DRAWINGS

FIG. 1 is a cross-sectional view illustrating a first exemplary configuration of a semiconductor device having a shield case;

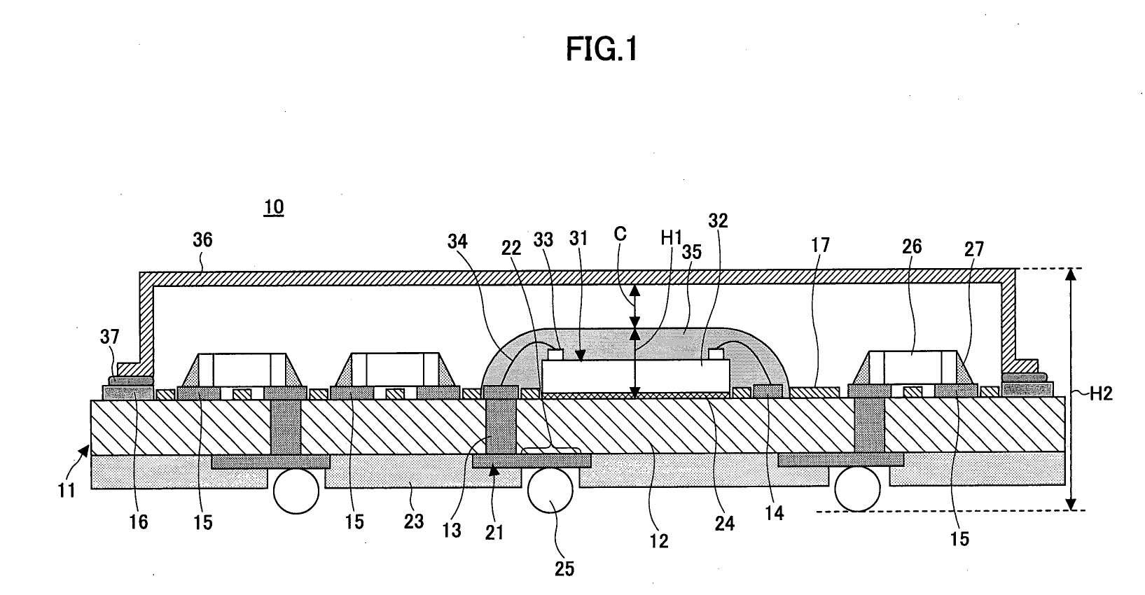

FIG. 2 is a cross-sectional view illustrating a second exemplary configuration of a semiconductor device having a shield case;

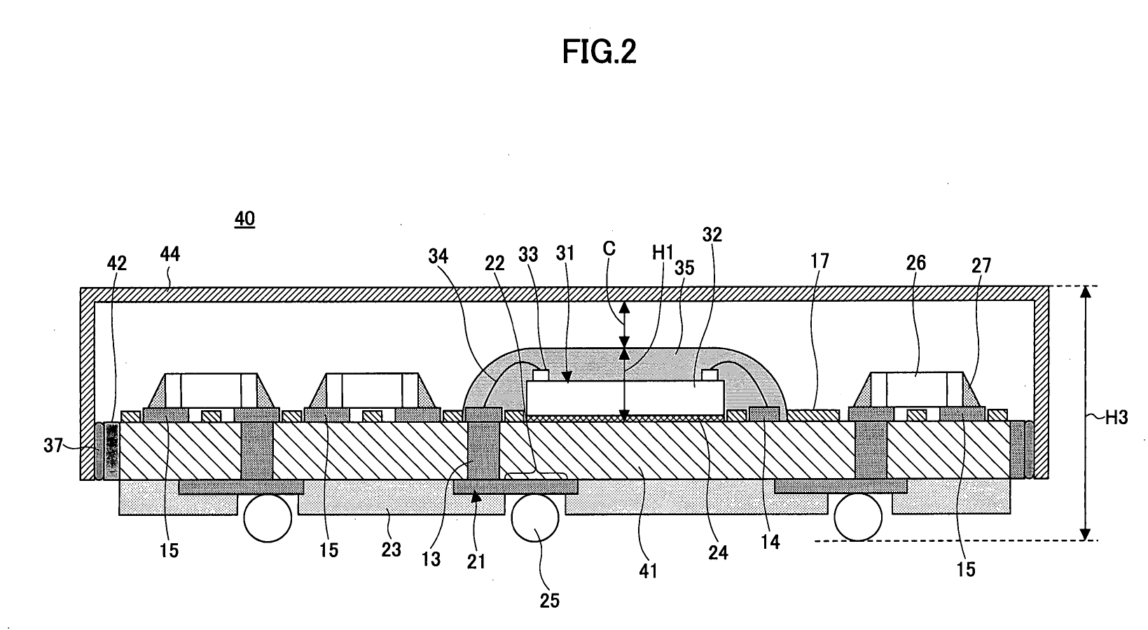

FIG. 3 is a cross-sectional view of a semiconductor device having a shield member according to an embodiment of the present invention;

FIG. 4 is a cross-sectional view of a semiconductor device having a shield member that is arranged into a sheet structure according to an embodiment of the present invention;

FIG. 5 is a plan view of a base material for fabricating a substrate according to an embodiment of the present invention;

FIG. 6 is a diagram illustrating a first process step for fabricating a semiconductor device according to an embodiment of the present invention;

FIG. 7 is a diagram illustrating a second process step for fabricating the semiconductor device according to the present embodiment;

FIG. 8 is a diagram illustrating a third process step for fabricating the semiconductor device according to the present embodiment;

FIG. 9 is a diagram illustrating a fourth process step for fabricating the semiconductor device according to the present embodiment;

FIG. 10 is a diagram illustrating a fifth process step for fabricating the semiconductor device according to the present embodiment;

FIG. 11 is a diagram illustrating a sixth process step for fabricating the semiconductor device according to the present embodiment;

FIG. 12 is a diagram illustrating a seventh process step for fabricating the semiconductor device according to the present embodiment;

FIG. 13 is a diagram illustrating an eighth process step for fabricating the semiconductor device according to the present embodiment; and

FIG. 14 is a plan view of the structure shown in FIG. 9.

### DETAILED DESCRIPTION OF THE PREFERRED EMBODIMENTS

In the following, preferred embodiments of the present invention are described with reference to the accompanying drawings.

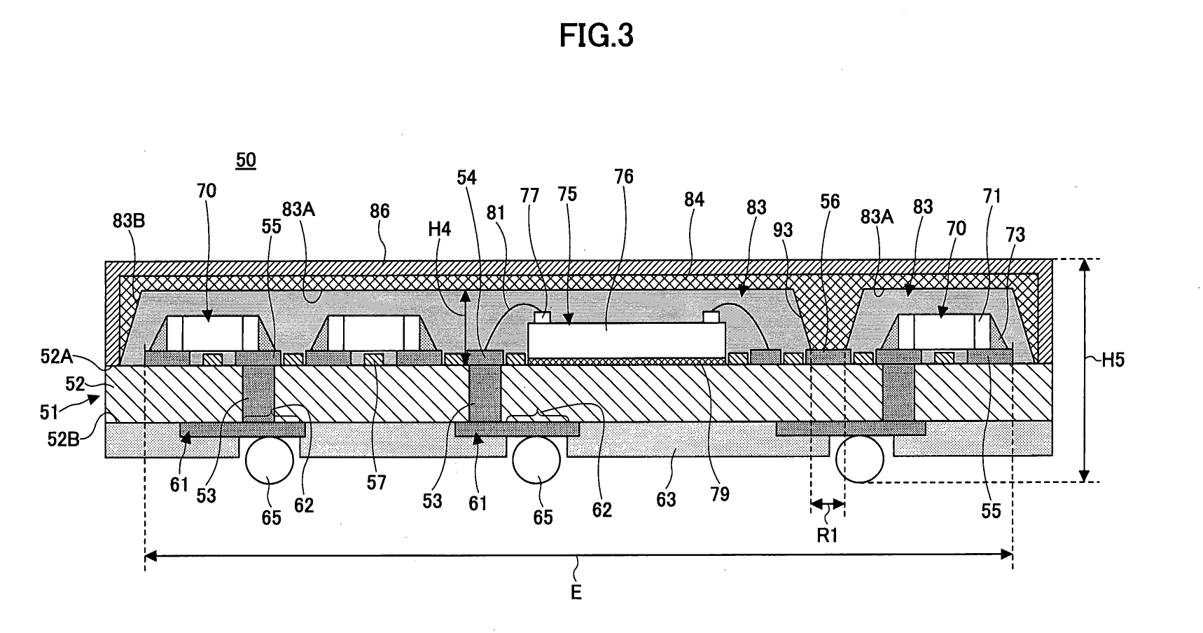

First, a semiconductor device 50 according to an embodiment of the present invention is described with reference to FIG. 3. FIG. 3 is a cross-sectional-view of the semiconductor device 50 according to the present embodiment. In this drawing, E denotes an electronic components mounting area located at a substrate 51 of the semiconductor device 50 in which electronic components (i.e., individual components 70 and a semiconductor chip 75 in the illustrated example) are mounted, H4 denotes the height of transfer molded resin 83 with respect to the upper surface 52A of base material 52 (simply referred to as height H4 hereinafter), and H5 denotes the height of the semiconductor device 50 (simply referred to as height H5 hereinafter).

The semiconductor device 50 is roughly made up of the substrate 51 and electronic components including the individual components 70 and the semiconductor chip 75, the transfer molded resin 83, and a shield member 86. The substrate 51 includes the base material 52, vias 53, connectors 54 and 55, a ground terminal 56, an insulating layer 57, wiring 61, solder resist 63, and solder balls 65. The vias 53 are configured to realize electrical connection between the connectors 54, 55 and the wiring 61.

The connectors 54 and 55 are arranged on the upper surface 52A of the base material 52 and are electrically connected to the vias 53. The connectors 54 are electrically connected to the semiconductor chip 75 by wires 81. The connectors 55 are electrically connected to the individual components 70.

The ground terminal 56 corresponds to a conductor with ground potential. The ground terminal 56 is located on the base material 52 at the inner side of the electronic components mounting area E of the substrate 51. By arranging the ground terminal 56 to be located within the electronic components mounting area E, the area of the base material 52 may be reduced, and in turn, the semiconductor device 50 may be miniaturized.

According to one embodiment, an index mark (not shown) used for mounting the semiconductor chip 75 or the individual components 70 or an identification mark (not shown) used for wire bonding may be set to ground potential so that it may be used as the ground terminal 56. By using the index mark or the identification mark as the ground potential 56, an area dedicated for the ground terminal 56 does not have to be secured at the base material 52, and the ground terminal 56 may be positioned within the electronic components mounting area E. It is noted that the semiconductor device 50 may include more than one ground terminal 56. The size of the ground terminal 56 may be approximately 0.5 mm□, for example.

The insulating layer 57 is arranged on the base material 52 to isolate the connectors 54 and 55 from each other. The wiring 61 includes connection pads 62 that are connected to the solder balls 65. The wiring 61 is arranged on the bottom surface 52B of the base material 52 and is connected to the vias 53. The solder resist 63 is arranged on the bottom surface 52B side of the base material 52 to expose the connection pads 62 and cover portions of the wiring 61 other than the connection pads 62. The solder balls 65 are connected to the connection pads 62. The solder balls 65 correspond to external connection terminals for connecting the semiconductor device 50 to another substrate such as a motherboard.

The individual components 70 corresponding to electronic components include electrodes 71. The electrodes 71 are configured to realize electrical connection between the individual components 70 and the connectors 55. The electrodes 71 are connected to the connectors 55 via solder paste 73. The individual components 70 may correspond to basic electric components such as a transistor, a diode, a resistor, and a capacitor, and each of the individual components is configured to realize one function (also referred to as ‘discrete components’).

The semiconductor chip 75 corresponding to an electronic component includes a semiconductor chip main part 76 and electrode pads 77. The side of the semiconductor main part 76 on which the electrode pads 77 are not mounted is adhered to the base material 52 via adhesive 79. The semiconductor chip 75 is electrically connected to the substrate 51 via gold wires 83, which realize connection between the electrode pads 77 and the connectors 54. In other words, the semiconductor device 75 is bear-chip mounted to the substrate 51.

The transfer molded resin 83 is arranged on the substrate 51 to cover the semiconductor chip 75 and the individual components 70 that are mounted within the electronic components mounting area E and expose the ground terminal 56. The transfer molded resin 83 has an opening 93 formed thereat for exposing the ground terminal 56. The diameter R1 of the lower bottom side opening portion of the opening 93 may be around 250-400 μm, for example.

The upper surface 83A of the transfer molded resin 83 is arranged into a smooth plane, and in this way, the shield member 86 may be pressed onto the transfer molded resin 83 upon adhering the shield member 86 to the transfer molded resin 83. By implementing such an arrangement, the height H5 of the semiconductor device 50 may be reduced compared to the heights H2 and H3 of the semiconductor devices 10 and 40 that use the potting resin 35 to seal the semiconductor chip 31. In this way, the semiconductor device 50 may be miniaturized with respect to the height directions. Also, the semiconductor device 50 may be easily mounted on another substrate such as a motherboard.

The transfer molded resin 83 corresponds to resin formed through transfer molding. Transfer molding involves setting a mold on a member that is to be sealed (i.e., the substrate 51 on which the individual components 70 and the semiconductor chip 75 are mounted in the illustrated example), applying pressure to resin that is heated and fluidized to inject the resin into the mold (pressure injection), and molding the resin into the shape of the mold. By sealing the individual components 70 and the semiconductor chip 75 using the transfer molded resin 83 that is formed through such a transfer molding process, the processing time required for sealing the individual components 70 and the semiconductor chip 75 may be reduced compared to the case of using the potting resin 35 so that productivity of manufacturing the semiconductor device 50 may be improved. It is noted that epoxy resin may be used as the transfer molded resin 83, for example.

The shield member 86 is arranged to cover the upper surface 83A and the side surface 83B of the transfer molded resin 83. The shield member 86 is adhered to the transfer molded resin 83 by conductive adhesive 84. The rim portion of the open side of the shield member 86 comes into contact with the upper surface 52A of the base material 52. The conductive adhesive 84 is forced into the opening 93 that is formed at the transfer molded resin 83 and in between the transfer molded resin 83 and the shield member 86. In this way, electrical connection may be realized between the ground terminal 56 and the shield member 86 via the conductive adhesive 84. It is noted that Ag paste may be used as the conductive adhesive 84, for example. As for the material of the shield member 86, Cu—Ni—Zn alloy may be used, for example. In such a case, the elements Cu, Ni, and Zn of the alloy may be arranged at a ratio of 62 wt %, 14 wt %, and 24 wt %, respectively, for example.

As can be appreciated from the above descriptions, by arranging the ground terminal 56 on the base material 52 so that it may be located within the electronic components mounting area E of the substrate 51 on which the individual components 70 and the semiconductor chip 75 are mounted, covering the individual components 70 and the semiconductor chip 75 with the transfer molded resin 83 while exposing the ground terminal, and realizing electrical connection between the shield member 86 and the ground terminal 56 with the conductive adhesive, the semiconductor device 50 may be miniaturized compared to the semiconductor devices 10 and 40. Also, by covering the individual components 70 and the semiconductor chip 75 with the transfer molded resin 83, the productivity of the semiconductor device 50 may be improved compared to the case of using potting resin. It is noted that the shape of the opening 93 is not limited to that of the illustrated example.

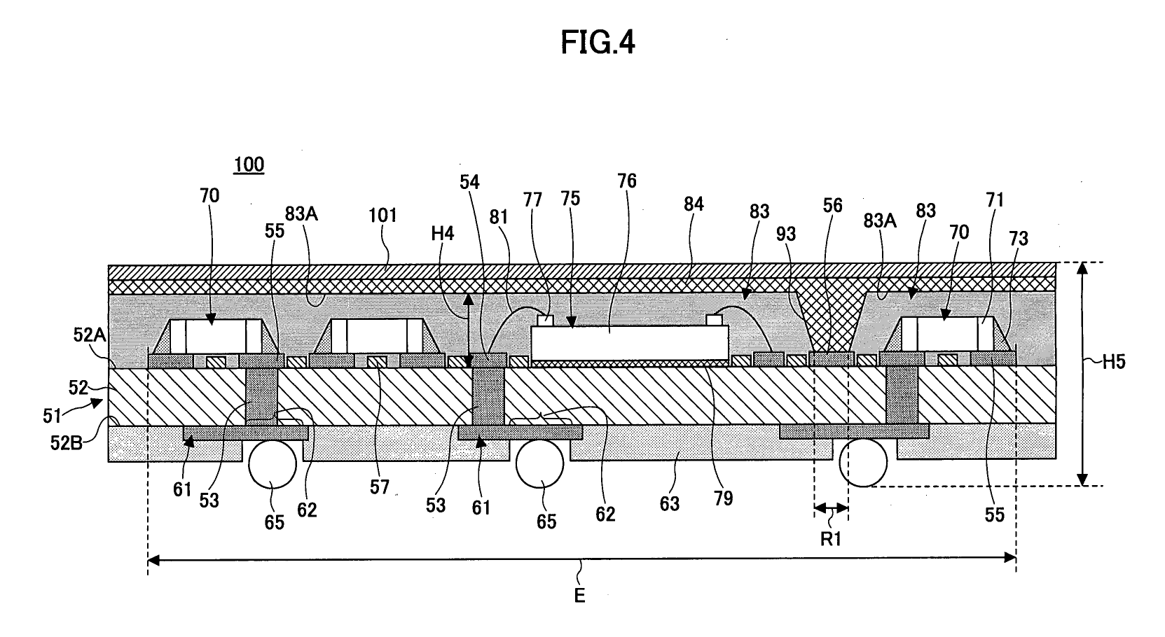

FIG. 4 is a cross-sectional view of a semiconductor device 100 having a shield member 101 that is formed into a sheet structure. It is noted that components of the semiconductor device 100 of FIG. 4 that are identical to those of the semiconductor device 50 of FIG. 3 are given the same numerical references. As is shown in FIG. 4, in the semiconductor device 100, the sheet-structured shield member 101 is arranged on the upper surface 83A of the transfer molded resin 83, and the shield member 101 and the ground terminal 56 are electrically connected by the conductive adhesive 84 to realize advantageous effects identical to those realized in the semiconductor device 50.

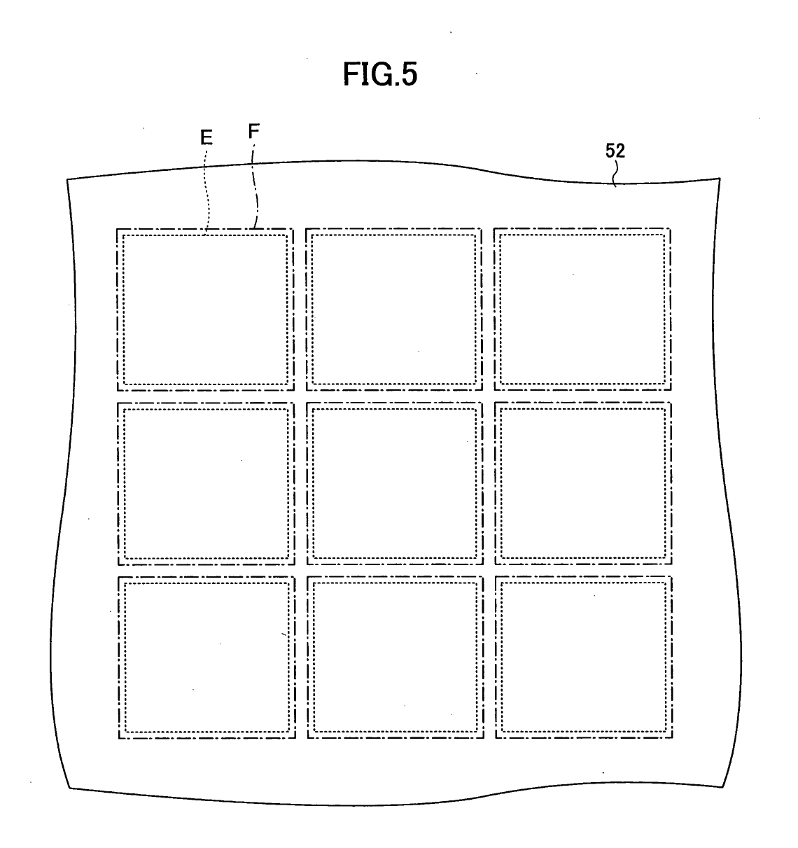

FIG. 5 is a plan view of the base material 52 for forming the substrate 51 according to an embodiment of the present invention. In FIG. 5, F represents an area in which the substrate 51 is formed (referred to as substrate forming area F hereinafter). As is shown in FIG. 5, plural substrates 51 are formed at plural substrate forming areas F of the base material 52. It is noted that in the illustrated example, the electronic components mounting area E is arranged to be located within the substrate forming area F.

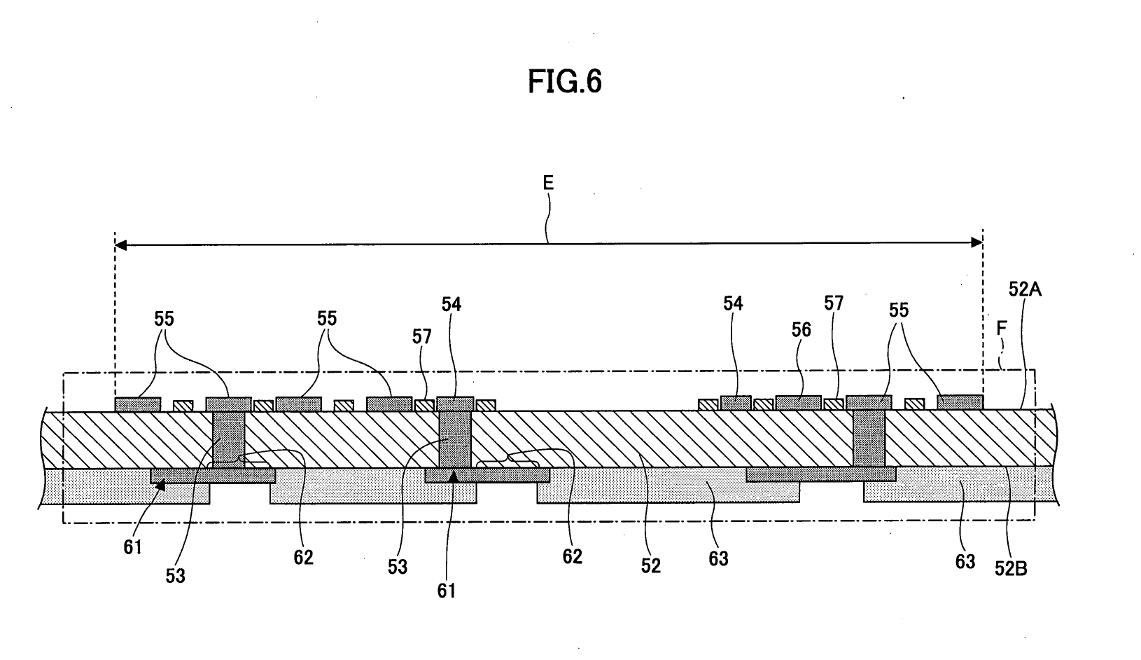

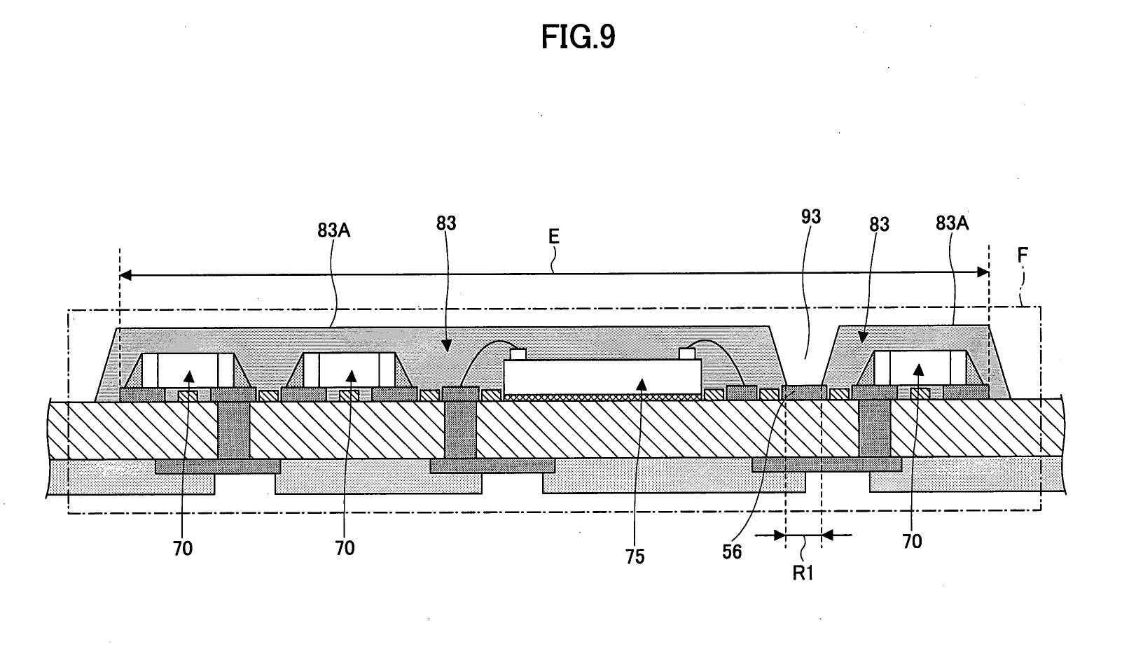

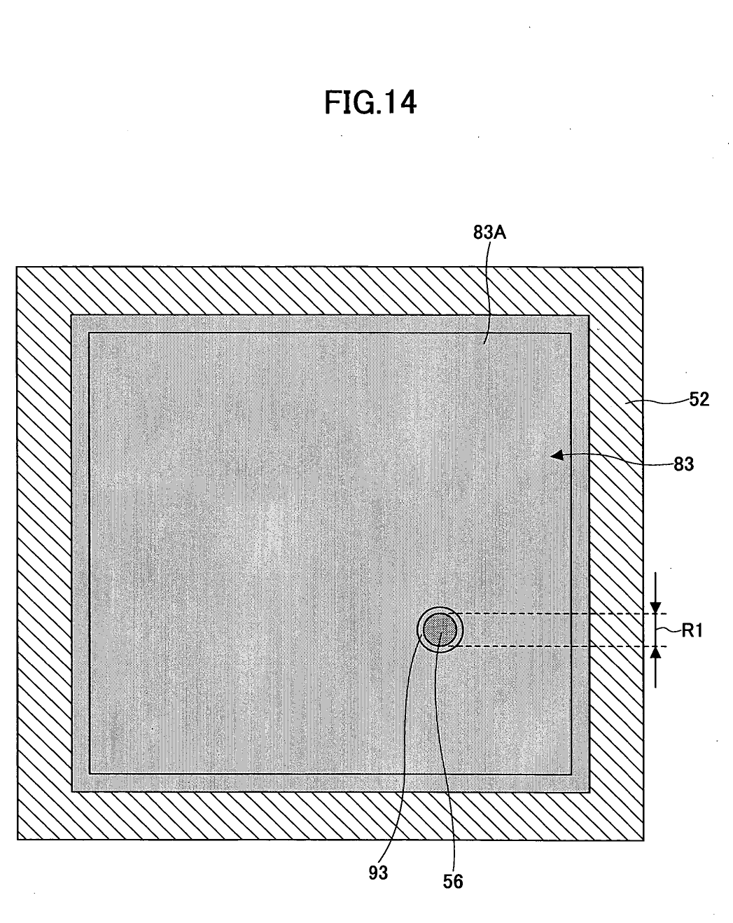

In the following, a method of fabricating the semiconductor device 50 is described with reference to FIGS. 6 through 14. FIGS. 6 through 13 illustrate process steps for fabricating the semiconductor device 50, and FIG. 14 is a plan view of the structure shown in FIG. 9. It is noted that in FIGS. 6 through 14, components that are identical to those of the semiconductor device 50 shown in FIG. 3 are given the same numerical references.

First, as is shown in FIG. 6, the vias 53 are formed on the base material 52, after which the connectors 54, 55, and the ground terminal 56 are formed at once within the electronic components mounting area E at the upper surface 52A of the base material 52. Then, the wiring 61 including the connection pads 62 is formed on the bottom surface 52B of the base material 52, after which the insulating layer 57 is formed on the upper surface 52A of the base material 52 and the solder resist 63 is formed on the bottom surface 52B of the base material 52.

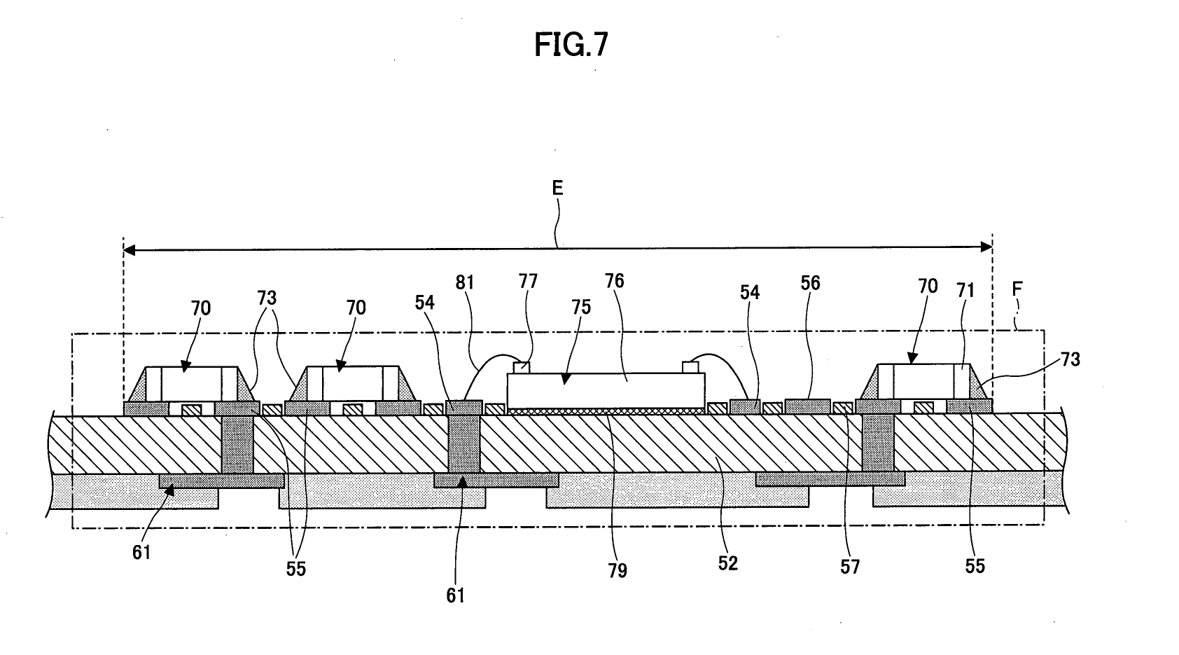

Then, as is shown in FIG. 7, the individual components 70 and the semiconductor chip 75 are connected to the substrate 51. Specifically, the electrodes 71 of the individual components 70 are connected to the connectors 55 by the solder paste 73, the semiconductor chip 75 is adhered to the upper surface 52A of the base material 52 by the adhesive 79, and the electrode pads 77 and the connectors 54 are interconnected by the wires 81.

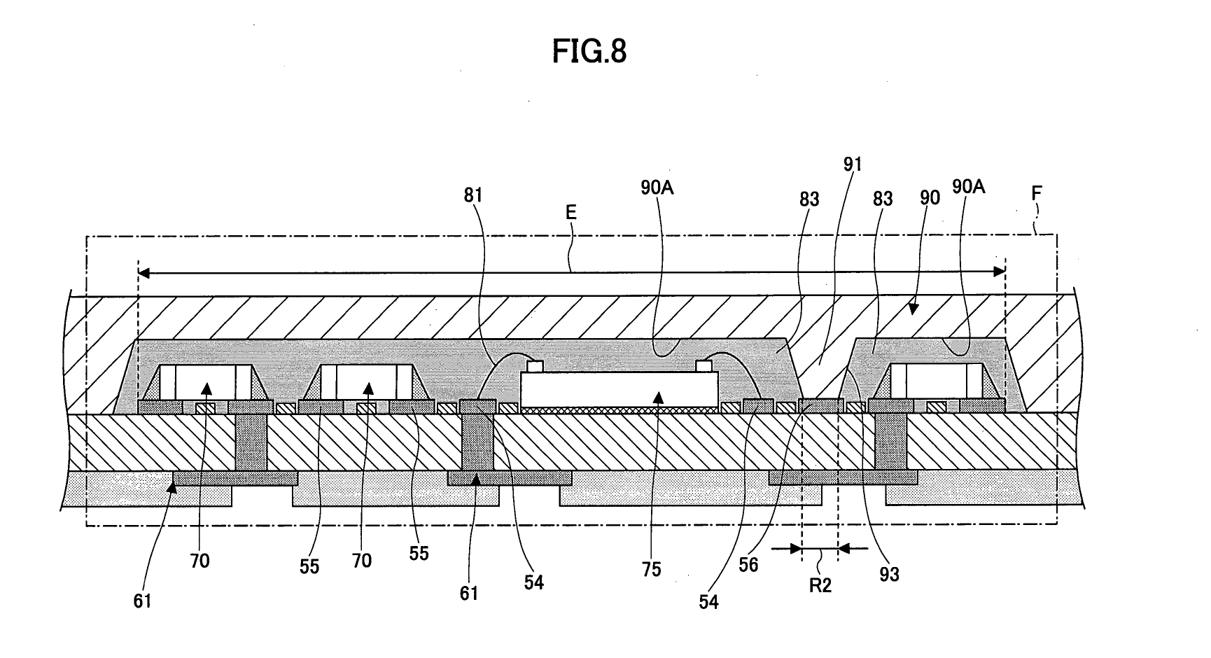

Then, as is shown in FIG. 8, a mold 90 having a convex portion 91 is placed on the base material 52 in a manner such that the convex portion 91 comes into contact with the ground terminal 56, and the transfer molded resin 83 is arranged between the mold 90 and the base material 52 through transfer molding. The convex portion 91 is configured to form the opening 93 at the transfer molded resin 83. The convex portion 91 of the mold 90 is arranged to match the ground terminal 56. For example, the bottom section of the convex portion 91 may have a diameter R2 of 250-400 μm.

The surface 90A of the mold 90 facing the base material 52 is arranged into a smooth plane. Then, as is shown in FIGS. 9 and 14, the mold 90 is removed so that the transfer molded resin 83 with the opening 93 exposing the ground terminal 56 and a smooth upper surface 83A is formed at the electronic components mounting area E. It is noted that the diameter R1 of the bottom opening portion of the opening 93 may be arranged to be around 250-400 μm, for example (i.e., R1=R2).

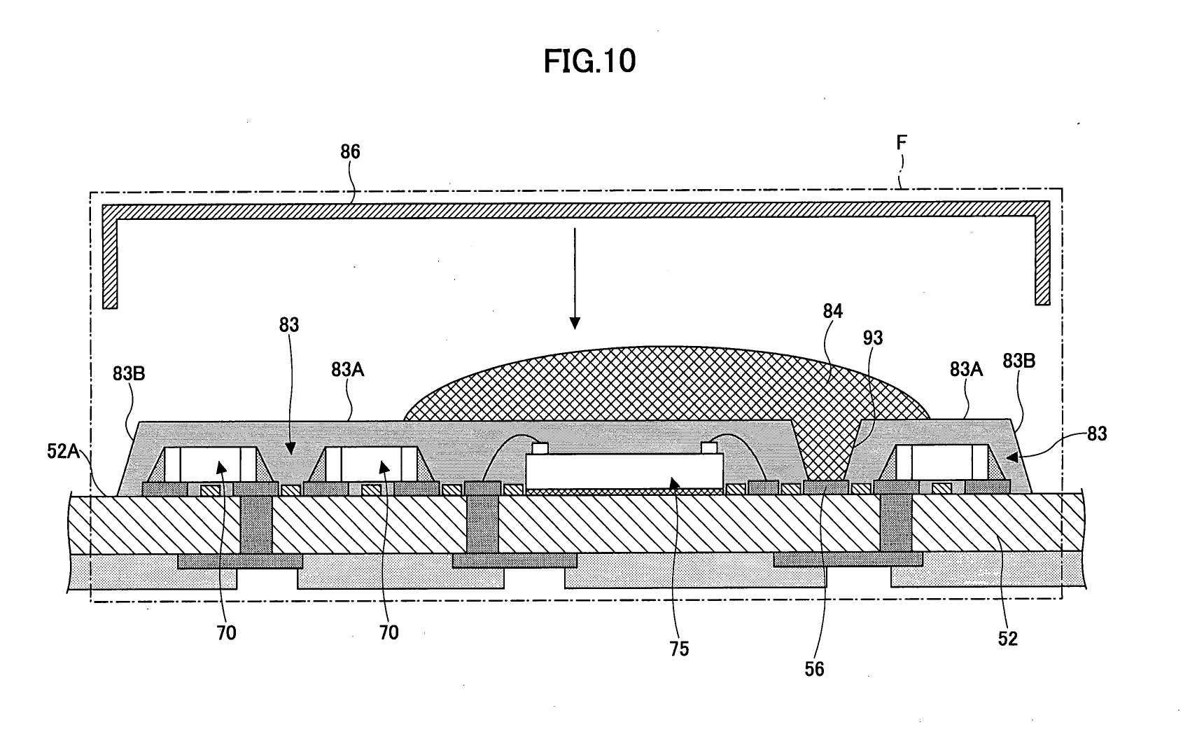

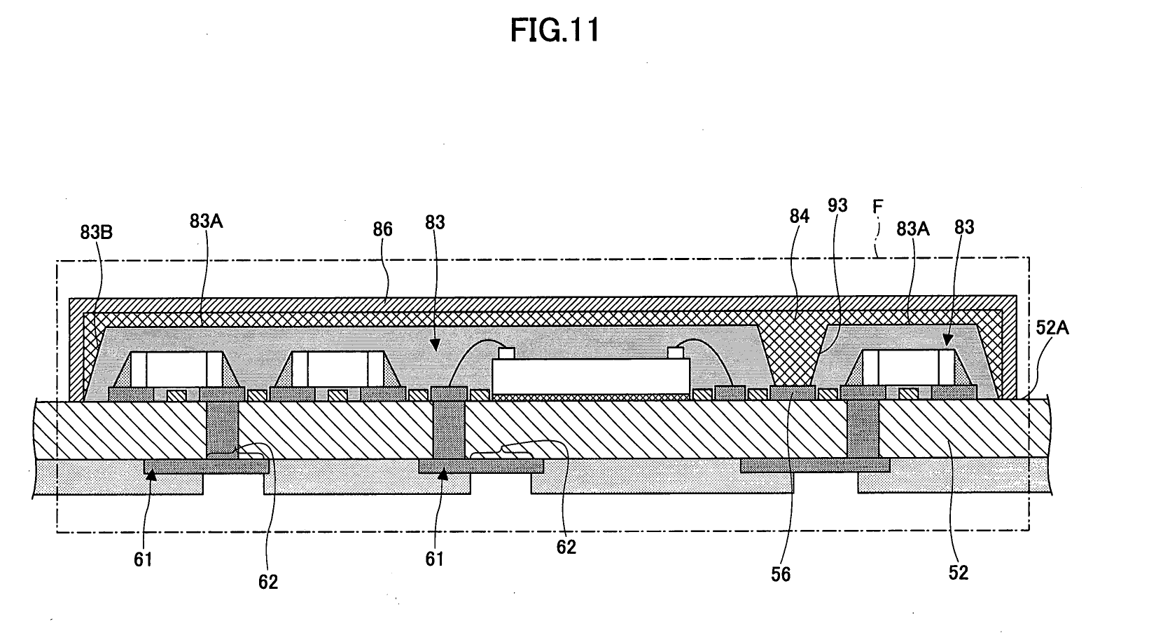

Then, as is shown in FIG. 10, the conductive adhesive 84 is arranged in the opening 93 and on the upper surface 83A of the transfer molded resin 83, and the shield member 86 is pressed to the transfer molded resin. In this way, as is shown in FIG. 11, the rim portion of the open side of the shield member 86 comes into contact with the upper surface 52A of the base material 52, and the shield member 86 is adhered to the transfer molded resin 83 by the conductive adhesive 84.

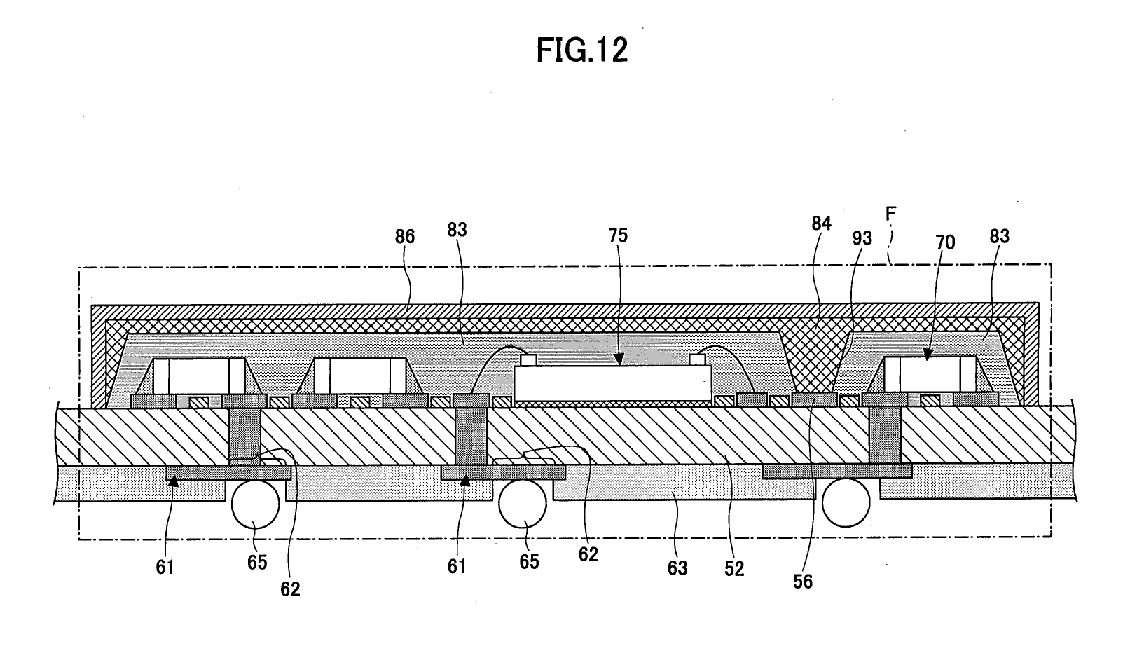

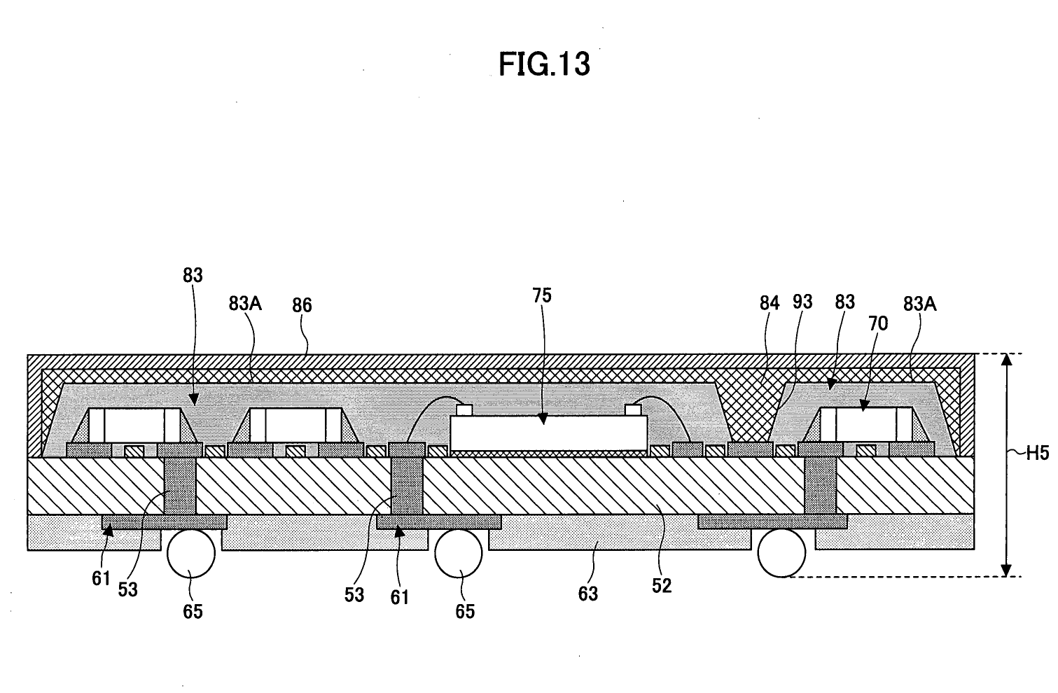

Then, as is shown in FIG. 12, the solder balls 65 are arranged on the connection pads 62. Then, a dicer is used to cut up and divide the base material 52 into individual semiconductor devices 50. FIG. 13 shows the semiconductor device 50 fabricated by performing the process steps described above.

As can be appreciated from the above descriptions, by arranging the transfer molded resin 83 to cover the individual components 70 and the semiconductor chips 75 mounted on plural substrate forming areas F at once through transfer molding, the productivity of the semiconductor device 50 may be improved compared to those of the semiconductor devices 10 and 40 that use potting resin.

Although the present invention is shown and described with respect to certain preferred embodiments, it is obvious that equivalents and modifications will occur to others skilled in the art upon reading and understanding the specification. The present invention includes all such equivalents and modifications, and is limited only by the scope of the claims. For example, the advantageous effects of the present invention may equally be realized in a case where a semiconductor chip is flip-chip connected to the base material 52. Also, the conductive adhesive 84 may be any element that is at least capable of realizing electrical connection between the ground terminal 56 and the shield member 56/101. In another example, the present invention may be applied to a semiconductor device that does not include the solder balls 65.

The present application is based on and claims the benefit of the earlier filing date of Japanese Patent Application No. 2004-346848 filed on Nov. 30, 2004, the entire contents of which are hereby incorporated by reference.

What is claimed is:

1. A semiconductor device, comprising:
a substrate;
a plurality of electronic components that are arranged at an electronic components mounting area of the substrate;
a ground terminal that is arranged within the electronic components mounting area;
a transfer molded resin that covers the electronic components while exposing the ground terminal;
a shield member that covers the electronic components and is connected to the ground terminal; and
a conductive adhesive that realizes electrical connection between the ground terminal and the shield member.

2. The semiconductor device as claimed in claim 1, wherein an upper surface of the transfer molded resin is arranged into a smooth plane.

3. The semiconductor device as claimed in claim 1, wherein the shield member is arranged into a sheet structure.
